(19) United States
(12) Patent Application Publication
(10) Pub. No.: US 2025/0138168 A1
(43) Pub. Date: May 1, 2025

(54) APPARATUS FOR DISRUPTING LIDAR

(71) Applicant: ATTOWAVE CO., LTD., Seoul (KR)

(72) Inventors: Sungchul KIM, Gwacheon-si Gyeonggi-do (KR); Sanggil PARK, Gunpo-si Gyeonggi-do (KR)

(73) Assignee: ATTOWAVE CO., LTD., Seoul (KR)

(21) Appl. No.: 18/496,595

(22) Filed: Oct. 27, 2023

(51) Int. Cl. G01S 7/495; G01R 19/00

(52) U.S. Cl. CPC G01S 7/495; G01R 19/0038

(57) ABSTRACT

A LIDAR disrupting apparatus is equipped with a transmitter, a receiver, a comparator, and a control unit. The transmitter emits probing signals and disrupting signals towards the LIDAR at different time intervals. The receiver receives reflected signals, which are reflections of the probing and disrupting signals, from the external environment and receives measurement signals emitted by the LIDAR. The comparator compares the voltage of the signals received in the receiver with a variable reference voltage. The control unit changes the reference voltage based on the output of the comparator while the reflected signals for the probing signals are received in the receiver. The control unit controls the transmitter to emit the disrupting signals during intervals when the disrupting signals are confirmed to be received based on the output of the comparator when measurement signals are received, and controls the transmitter to emit the probing signals during intervals when disrupting signals are not emitted.

### BACKGROUND

### Technical Field

The present invention relates to a LIDAR disrupting apparatus, and more specifically, to a LIDAR disrupting apparatus that disrupts the measurement operation of a LIDAR by transmitting signals for disrupting the measurement signals emitted from the LIDAR.

### Background of the Invention

A device for measuring the speed or distance of a target object, such as LIDAR (Light Detection and Ranging), has been developed. LIDAR emits measurement signals consisting of multiple pulses towards the target object and receives pulses reflected from the target object, thereby measuring the distance and speed of the target object.

A LIDAR disrupting apparatus disrupts the distance and speed measurement operations of LIDAR by emitting disrupting signals of a pulse timing similar to that of the measurement signals towards LIDAR. This prevents LIDAR from reading the pulses reflected from the target object.

FIG. 1 shows the pulse timing of the measurement signals emitted by LIDAR and the disrupting signals emitted by the disrupting apparatus.

The transmitter of LIDAR generates pulses at regular intervals, and these measurement signals are received by the receiver of the disrupting apparatus. Depending on how many measurement signals are received by the receiver of the disrupting apparatus, the disrupting apparatus determines the timing t11, t12 and t13 of the generation of these measurement signals. Consequently, the transmitter of the disrupting apparatus generates disrupting signals synchronized with the timing of the measurement signals. The receiver of the LIDAR receives both the reflected signals from the measurement signals sent by LIDAR and the disrupting signals sent by the disrupting apparatus. As a result, LIDAR malfunctions in measuring the speed and distance of the target object using the received signals. To perform such disrupting, the disrupting signals of the disrupting apparatus must have precise emission timing coordinated with the LIDAR measurement signals.

The timing t11, t12 and t13 of the emission of the measurement signals from LIDAR can sometimes be constant, but it can also change continuously in some LIDARs. Therefore, accurate measurement of the emission timing is essential for controlling the emission timing of the disrupting signals. The disrupting apparatus continuously receives the measurement signals sent by LIDAR, measures the emission timing of these measurement signals, and adjusts the emission timing of the disrupting signals accordingly.

However, when the disrupting signals generated by the disrupting apparatus are reflected back and received by the disrupting apparatus, the measurement signals from the LIDAR and the reflected signals of the disrupting signals are received together at the receiver of the disrupting apparatus. In this case, the disrupting apparatus cannot distinguish LIDAR's measurement signals. Therefore, the disrupting apparatus must include a solution to block the reflected signals of the disrupting signals.

Moreover, the surroundings of the disrupting apparatus are not constant, and the amount of reflection of the disrupting signals also varies depending on the environment. Therefore, if the sensitivity of the receiver in the disrupting apparatus remains fixed, it cannot effectively block the reflected signals of the disrupting signals. Additionally, it is necessary to maximize the sensitivity of the receiver within the limits of blocking the reflected signals of the emitted disrupting signals. In other words, the receiver of the disrupting apparatus needs to control its sensitivity to change rapidly in response to the amount of reflection of the disrupting signals.

U.S. Pat. No. 8,309,926 (Pulse-Laser Beam Detector with Improved Sun and Temperature Compensation) suggests a method where probing signals are emitted before the disrupting signals, and the receiver determines the detection of the probing signals to adjust the receiver's sensitivity. In this case, the gain of the receiver of the disrupting apparatus is adjusted for sensitivity control. However, this approach, when applied in practice, does not result in optimal performance due to component variations and environmental changes such as temperature fluctuations.

### SUMMARY OF THE INVENTION

The object of the present invention is to provide a LIDAR disrupting apparatus that effectively blocking the reflected signals of emitted disrupting signals while maximizing the receiver sensitivity, by adaptively changing the sensitivity of the receiver based on the amount of the reflection of the disrupting signals.

To achieve of the object, the present invention provides a LIDAR disrupting apparatus comprising: a transmitter for emitting probing signals and disrupting signals towards the LIDAR, respectively at different time intervals; a receiver for receiving reflected signals which are reflections of the probing signal and the disrupting signals from an external environment, and receiving measurement signals emitted by the LIDAR; a comparator for comparing a voltage of signals received in the receiver with a reference voltage which is variable; and a control unit for changing the reference voltage based on an output of the comparator while the reflected signals for the probing signals are received in the receiver, and for controlling the transmitter based on the output of the comparator so that the disrupting signals are emitted while the measurement signals are confirmed and the probing signals are emitted while the disrupting signals are not emitted.

It is preferable that the control unit controls the transmitter to emit the disrupting signals and the probing signals alternately.

The control unit comprises: an MCU that outputs a first control signal corresponding to the output of the comparator while the reflected signals for the probing signals are received in the receiver, and outputs a second control signal for controlling emission timing of the probing signals and the disrupting signals based on the output of the comparator while the reflected signals for the disrupting signals are received in the receiver; a DAC that receives the first control signal to output the reference voltage; and a driver controlled by the second control signal to drive emission of the probing signals and the disrupting signals of the transmitter.

The MCU can generate the first control signal so that the reference voltage changes with a larger range as the reference voltage is greater in magnitude.

The MCU can generate the first control signal so that the reference voltage changes with a larger range when the reference voltage is changed in increasing direction in magnitude compared to when the reference voltage is changed in decreasing direction in magnitude.

According to the present invention, the sensitivity of the receiver of the LIDAR disrupting apparatus changes adaptively according to the reflection amount of the disrupting signals used to disrupt the measurement signals from the LIDAR. Therefore, it is possible to effectively block the reflected signals of the emitted disrupting signals while maximizing the sensitivity of the receiver of the LIDAR.

### BRIEF DESCRIPTION OF THE DRAWINGS

FIG. 1 illustrates the pulse timing of the measurement signals emitted by a LIDAR and the disrupting signals emitted by a disrupting apparatus.

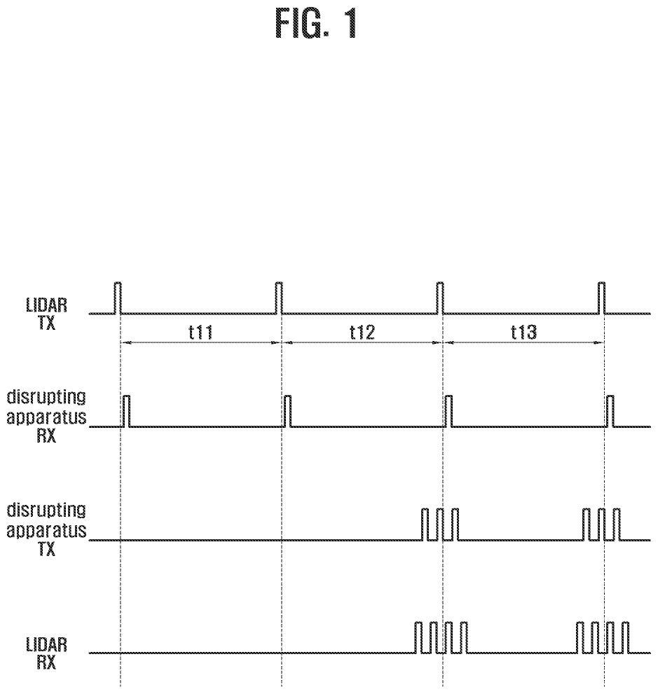

FIG. 2 is a block diagram of the LIDAR disrupting apparatus according to the present invention.

FIG. 3 is a diagram showing the signal transmission and reception timing of the LIDAR disrupting apparatus of FIG. 2.

FIG. 4 depicts a diagram illustrating the process of changing the reference voltage.

### PREFERRED EMBODIMENT OF THE INVENTION

The following explains the invention in more detail with reference to the drawings.

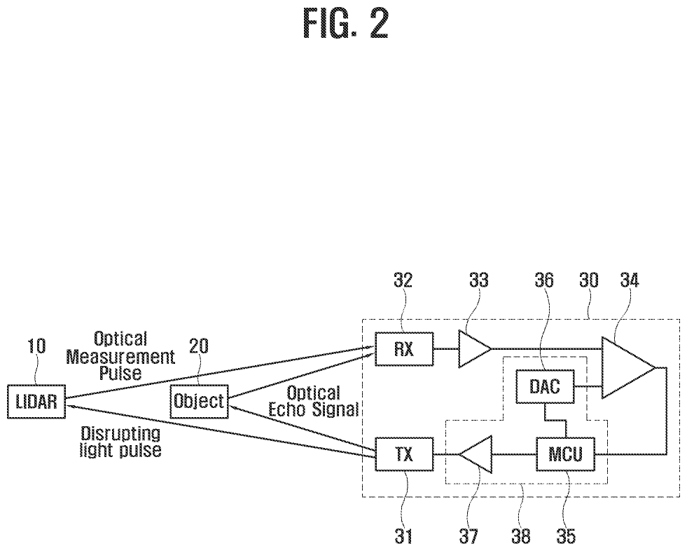

FIG. 2 is a block diagram of the LIDAR disrupting apparatus according to the present invention. The LIDAR disrupting apparatus 30 of the present invention comprises a transmitter 31, a receiver 32, a comparator 34, and a control unit 38.

The transmitter 31 emits probing signals and disrupting signals towards the LIDAR 10. The transmitter 31 emits the probing signals and the disrupting signals at different time intervals, and the emitting timing is controlled by the control unit 38. Specifically, the transmitter 31 first emits the probing signals and then emits the disrupting signals, and the emission of the probing signals occurs before each emission of the disrupting signals.

The receiver 32 receives signals from the external environment. The signals received by the receiver 32 include the measurement signals emitted by the LIDAR and the reflected signals of the probing signals and the disrupting signals. When the transmitter 31 emits the probing signals towards the LIDAR 10, a portion of these probing signals is reflected by objects 20 outside and received as reflected signals by the receiver 32. Similarly, when the transmitter 31 emits the disrupting signals towards the LIDAR 10, a portion of these disrupting signals is received as reflected signals by the receiver 32. The signals received by the receiver 32 are then amplified by an amplifier 33 before being input to the comparator 34.

The comparator 34 compares the voltage that has been received by the receiver 32 and then amplified by the amplifier 33 with a reference voltage. The comparator 34 outputs a pulse when the voltage input is greater than the reference voltage. Therefore, the comparator 34 functions to detect signals with voltages greater than the reference voltage among the received signals. The reference voltage is a variable voltage, and its value is determined by the control unit 38.

The control unit 38 performs control actions to change the reference voltage and control actions to control the timing of the emission of the probing signals and the disrupting signals. Specifically, while the reflected signals of the probing signals are received by the receiver 32, the control unit 38 changes the reference voltage based on the output of the comparator 34. Additionally, the control unit 38 controls the transmitter 31, based on the output of the comparator 34, to emit the disrupting signals while the measurement signals are confirmed and to emit the probing signals while the disrupting signals are not emitted. The control unit 38 includes an MCU 35, a DAC (Digital-to-Analog Converter) 36, and a driver 37.

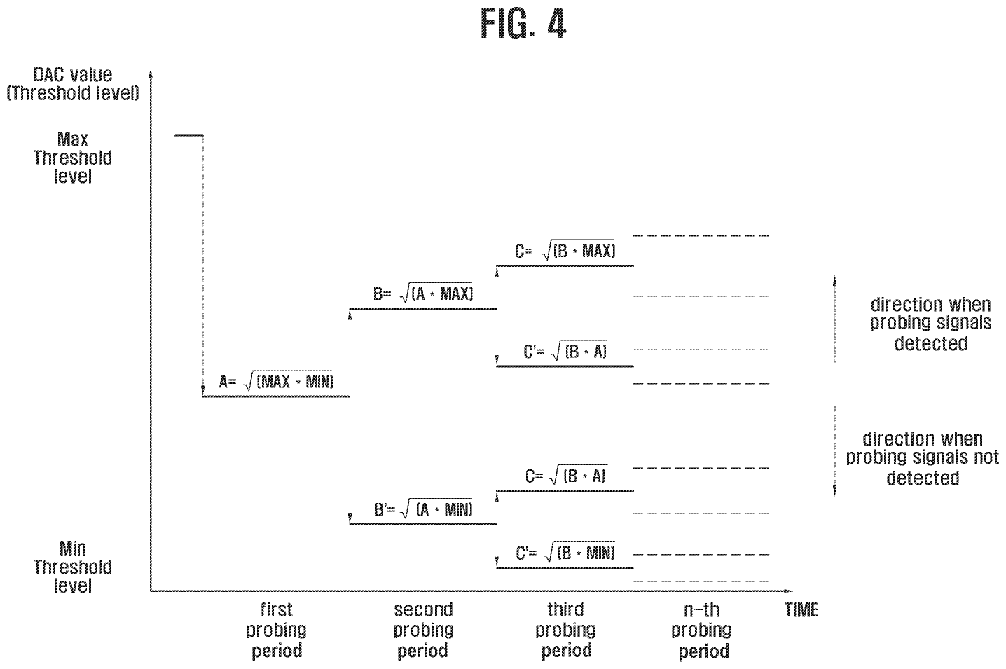

The MCU 35 outputs a first control signal corresponding to the output of the comparator 34 while the reflected signals of the probing signals are received by the receiver 32. That is, the reflected signals of the probing signals are received by the receiver 32 while the probing signals are emitted. When the reflected signals of a voltage greater than the reference voltage are input to the comparator 34, the comparator 34 outputs a pulse, and when the reflected signals with a voltage lower than the reference voltage are input to the comparator 34, the comparator 34 does not output a pulse. The MCU 35 determines the voltage level of the reflected signals based on the output pulses of the comparator 34, and then generates the first control signal to increase or decrease the level of the reference voltage accordingly. In detail, when the comparator 34 outputs a pulse, the MCU 35 interprets it as a higher voltage level of the reflected signals compared to the current reference voltage, and generates the first control signal to increases the reference voltage accordingly. When the comparator 34 does not output a pulse, the MCU 35 interprets it as a lower voltage level of the reflected signals compared to the current reference voltage, and generates the first control signal to decreases the reference voltage accordingly. The detailed method for generating the first control signal is explained later in greater detail with reference to FIG. 4.

As the reference voltage decreases, the sensitivity of the receiver of the LIDAR disrupting apparatus 30 for the measurement signals generated by the LIDAR 10 increases, as will be explained later. This means that when the measurement signals are received by the receiver 32 and then input to the comparator 34, even if the voltage level of the measurement signals received by the receiver 32 is relatively low, it can still be detected by the comparator 34. Accordingly, the measurement signals of low voltage level can also be detected.

The DAC 36 converts the first control signal into an analog signal to generate the reference voltage. The generated reference voltage is applied to the comparator 34, so the changed reference voltage is applied to the comparator 34. Since the transmitter 31 alternates between emitting the probing signals and emitting the disrupting signals, the reflected signals of the disrupting signals are received by the receiver 32 after the measurement signals has been emitted and the reference voltage has been changed accordingly. In such a situation, as the disrupting signals are emitted in sync with the emitting timing of the measurement signals emitted by the LIDAR 10, the measurement signals of the LIDAR 10 are also received by the receiver 32 when the reflected signals from the disrupting signals are received. That is, immediately after the emission of the disrupting signals, the receiver 32 receives both the measurement signals and the reflected signals from the disrupting signals. The received signal at the receiver 32 is amplified by the amplifier 33 and then input to the comparator 34, and the comparator 34 outputs pulses when a voltage greater than the reference voltage applied to the comparator 34 is input. In this situation, the measurement signals are in higher voltage level than the reflected signals of the disrupting signals. Accordingly, among the signals input to the comparator 34, the reflected signals from the disturbing signals are removed by the reference voltage, and only the pulses corresponding to the measurement signals emitted by the LIDAR 10 are output from the comparator 34. The output pulses are provided to MCU 35.

As mentioned earlier, the reference voltage is changed based on the probing signals immediately before the emission of the disrupting signals. This changed voltage has been set to be greater than the magnitude necessary to remove the reflected signals and to be as low as possible. Consequently, the reflected signals of the disrupting signals are removed while the sensitivity of the receiver for the measurement signals is enhanced.

The MCU 35 outputs a second control signal based on the output of the comparator 34 while the measurement signals from the LIDAR 10 and the reflected signals from the probing signals are received by the receiver 32. The MCU 35 can measure the timing of the emission of the measurement signals, since the output of the comparator 34 includes only the pulses of the measurement signals. The second control signal is used to control the driver 37 according to the measured timing of the emission of the measurement signals.

The driver 37 is controlled by the second control signal and drives the emission of the probing signals and the disrupting signals from the transmitter 31. Specifically, the driver 37 controls the transmitter 31 to emit the disrupting signals in sync with the timing of the measurement signals emitted by the LIDAR 10 and also controls the transmitter 31 to emit the probing signals in alternation with the disrupting signals.

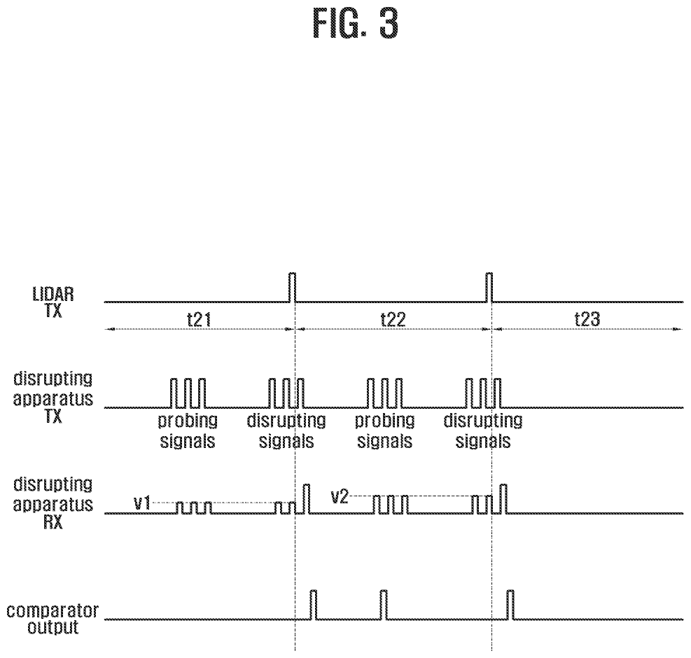

FIG. 3 is a diagram showing the signal transmission and reception timing of the LIDAR disrupting apparatus of FIG. 2. The LIDAR 10 emits the measurement signals with the time intervals t21, t22 and t23 based on predetermined transmission timings. The transmitter 31 of the disrupting apparatus 30 generates the disrupting signals according to the transmission timing of the measurement signals of the LIDAR, and generates the probing signals before the generation of disrupting signals. The disrupting signals and the probing signals can be composed of a same signal pattern, and, as shown in FIG. 3, each may consist of several pulses. While FIG. 3 illustrates three pulses for both of the disrupting signals and the probing signals, they can, for example, be composed of five pulses.

In the receiver 32 of the disrupting apparatus 30, the reflected signals and the measurement signals are received together. When the probing signals are emitted, only the reflected signals of the probing signals are received immediately after the emission of the probing signals. When the disrupting signals are emitted, both the reflected signals of the disrupting signals and the measurement signals are received. The voltage level of the reflected signals is smaller compared to the measurement signals. In FIG. 3, for example, during the t21 interval, the voltage v1 of the reflected signals of the probing signals is assumed to be lower than the current reference voltage. During the t22 interval, the voltage v2 of the reflected signals of the probing signals is assumed to be higher than the current reference voltage. In the t21 interval, the comparator 34 does not detect the reflected signals of the probing signals, and consequently, the reference voltage is decreased relative to the previous interval, t21. In the t22 interval, the comparator 34 detects the reflected signals of the probing signals, and thus, the reference voltage is increased relative to the t21 interval.

In this manner, as the voltage of the reflected signals from the probing signals increases or decreases, the reverence voltage increases or decreases accordingly, so the level of the voltage used for the reverence to remove the signals deemed as the reflected signals are changed adaptively. Therefore, the reflected signals can be removed even when the magnitude of the reflected signals become great, and to the contrary, the reflected signals can be removed and the sensitivity of the receiver 32 is enhanced even when the magnitude of the reflected signals become small. Accordingly, the measurement signals from the LIDAR 10 can be detected accurately.

Meanwhile, in changing the magnitude of the reference voltage, it is preferable that the larger the current reference voltage, the larger the range of change of the reference voltage. In other words, when the current reference voltage is relatively low, the range of change concerning the detection of the reflected signals should be relatively small, and when the reference voltage is relatively high, the range of change should be relatively large. This ensures that changes in the reference voltage can occur more swiftly and effectively, taking into account the current level of the reference voltage.

Furthermore, in changing the magnitude of the reference voltage, it is preferable that the change range is larger when the reference voltage increases compared to wen the reference voltage decreases. This means that even for the same reference voltage, the changed amount of the reference voltage is greater if the reference voltage is being changed to be higher, and the changed amount of the reference voltage is smaller if the reference voltage is being changed to be lower, thereby allowing for more rapid adaptive reference voltage changes.

An example of implementing this reference voltage change method is illustrated in FIG. 4.

Initially, before the emission of the first probing signals (e.g., during the t21 interval in FIG. 3), the reference voltage A is set to the geometric mean of the maximum value MAX and minimum value MIN. Here, the maximum value MAX and the minimum value Min are respectively the maximum value and the minimum value that the disturbing apparatus can set as the reference voltage within the range of adjustable reference voltages.

After the emission of the first probing signals, when changing to a new reference voltage (e.g., during the t21 interval in FIG. 3), the reference voltage B is determined as the geometric mean of the current reference voltage A and either the maximum value MAX or the minimum value MIN. In detail, the reference voltage B is determined as the geometric mean of the current reference voltage A and the maximum value MAX if the reflected signals are detected in the comparator 34 as a result of the emission of the probing signals, and the reference voltage B is determined as the geometric mean of the current reference voltage A and the minimum value MIN if the reflected signals are not detected in the comparator 34 as a result of the emission of the probing signals. Therefore, the reference voltage is changed to a higher reference voltage B when the reflected signals are detected, and the reference voltage is changed to a lower reference voltage B′ when the reflected signals are not detected.

Subsequent change to the reference voltage (e.g., during the t22 interval in FIG. 3) is determined by the geometric mean of the current reference voltage B or B′ and the reference voltage A determined in the previous interval t21. In this situation if the use of the previous reference voltage A is not proper in consideration of the direction to change the voltage, the maximum value MAX or the minimum value MIN can be used in substitution for the previous reference voltage A. Specifically, when increasing the reference voltage, if the previous reference voltage A is higher than the current reference voltage B or B′, the previous reference voltage A is used, and otherwise, the maximum value MAX is used. When decreasing the reference voltage, if the previous reference voltage A is lower than the current reference voltage B or B′, the previous reference voltage A is used, and otherwise, the minimum value MIX is used. This leads to the determination of a higher reference voltage C when the reflected signals are detected, and the determination of a lower reference voltage C′ when the reflected signals are not detected. As such a process is repeated in every time interval, the change of the reference voltage is performed at each time interval.

In summary, the present invention allows adaptive changes to the reference voltage used as a reference to remove the disturbing signals, based on increases or decreases in the voltage of the reflected signals from the probing signals. This ensures that the reflected signals can be removed effectively even when the magnitude of the reflected signals increases, and sensitivity for receiving the measurement signal is enhanced and the reflected signals are removed even when the magnitude of the reflected signals decreases.

Although details of the disclosure have been described above through a few embodiments of the disclosure with reference to the accompanying drawings, the embodiments are merely for the illustrative and descriptive purposes only but not construed as limiting the scope of the disclosure defined in the appended claims. It will be understood by a person having ordinary skill in the art that various changes and other equivalent embodiments may be made from these embodiments. Thus, the scope of the invention should be defined by the technical subject matters of the appended claims.

What is claimed is:

1. A LIDAR disrupting apparatus comprising:
a transmitter for emitting probing signals and disrupting signals towards the LIDAR, respectively at different time intervals;
a receiver for receiving reflected signals which are reflections of the probing signal and the disrupting signals from an external environment, and receiving measurement signals emitted by the LIDAR;
a comparator for comparing a voltage of signals received in the receiver with a reference voltage which is variable; and
a control unit for changing the reference voltage based on an output of the comparator while the reflected signals for the probing signals are received in the receiver, and for controlling the transmitter based on the output of the comparator so that the disrupting signals are emitted while the measurement signals are confirmed and the probing signals are emitted while the disrupting signals are not emitted.

2. The LIDAR disrupting apparatus of claim 1, wherein the control unit controls the transmitter to emit the disrupting signals and the probing signals alternately.

3. The LIDAR disrupting apparatus of claim 1, wherein the control unit comprises:
an MCU that outputs a first control signal corresponding to the output of the comparator while the reflected signals for the probing signals are received in the receiver, and outputs a second control signal for controlling emission timing of the probing signals and the disrupting signals based on the output of the comparator while the reflected signals for the disrupting signals are received in the receiver;
a DAC that receives the first control signal to output the reference voltage; and
a driver controlled by the second control signal to drive emission of the probing signals and the disrupting signals of the transmitter.

4. The LIDAR disrupting apparatus of claim 3, wherein the MCU generates the first control signal so that the reference voltage changes with a larger range as the reference voltage is greater in magnitude.

5. The LIDAR disrupting apparatus of claim 3, wherein the MCU generates the first control signal so that the reference voltage changes with a larger range when the reference voltage is changed in increasing direction in magnitude compared to when the reference voltage is changed in decreasing direction in magnitude.
